(19) United States
(12) Patent Application Publication
(10) Pub. No.: US 2025/0149813 A1
(43) Pub. Date: May 8, 2025

(54) Card Edge Connector System

(71) Applicant: Carlisle Interconnect Technologies, Inc., St. Augustine, FL (US)

(72) Inventors: Shawn Murphy, Portland, OR (US); Kelsey Fisher, Portland, OR (US); Emad Soubh, Vancouver, WA (US)

(21) Appl. No.: 19/013,014

(22) Filed: Jan. 8, 2025

Related U.S. Application Data
(63) Continuation of application No. 17/627,457, filed on Jan. 14, 2022, now abandoned.
(60) Provisional application No. 62/874,682, filed on Jul. 16, 2019.

(51) Int. Cl. H01R 12/72; H05K 1/02; H05K 1/14; H05K 3/36

(52) U.S. Cl. CPC H01R 12/721; H05K 1/0224; H05K 1/141; H05K 3/366

(57) ABSTRACT

A card edge connector system includes a socket body 12 forming a socket 14 having opposing sides 16 and a bottom 19. A plurality of spring elements 20 are positioned along at least one of the opposing sides of the socket and form a plurality of spring fingers 22 flexing inwardly in the socket. A ground contact 40 is positioned on the bottom of the socket 14 and includes a spring finger 42 configured for flexing upwardly in the socket. A printed circuit board 26 having opposing sides 36, 38 and an edge 46 includes data signal patterns 32, 34 plated on a side of the board for handling a data signal. A ground pattern 62 is plated on each of the opposing sides of the board and a ground pattern 64 is plated on an edge of the board. Other ground layers 66 are positioned within the printed circuit board and electrically coupled with the ground patterns on the opposing sides and the ground pattern 64 on the edge of the board so that when the printed circuit board is received in the socket, the spring fingers engages the data signal pattern and the spring finger of the ground contact engages the edge of the board.

### FIELD OF THE INVENTION

This invention is directed generally to an electrical connector system and particularly to a connector system for interfacing with a circuit card.

### BACKGROUND OF THE INVENTION

Card edge connectors are used in various system applications. For example, card edge connector systems are typically mounted to a host circuit board. The card edge connectors include card slots for receiving a card edge of a printed circuit board or card of a pluggable circuit or module. For example, such pluggable modules with cards may be modules including electrical components thereon, such as memory, processors and the like forming electrical circuits that interact with the host circuit board and its components. Generally, such card edge connectors provide the desirable electrical connections and ground signals and are designed for supporting the stand-alone plug-in modules.

One issue to be addressed for improving performance in card edge connector systems is to reduce signal loss at the transition through the connector and a printed circuit card hard edge. It is also desirable to improve signal integrity. Accordingly, the present invention addresses such issues in an improved card edge connector system design.

### BRIEF DESCRIPTION OF THE DRAWINGS

The accompanying drawings, which are incorporated in and constitute a part of this specification, illustrate embodiments of the invention, and together with a general description of the invention given above and the detailed description given below serve to explain the invention.

FIG. 1 is a perspective view of a card edge connector system in accordance with the invention.

FIG. 2 is an exploded view of a card edge connector system as illustrated in FIG. 1.

FIG. 3 is a perspective view of a card edge connector system of the invention implemented with opposing cards.

FIG. 4 is a perspective view of the system as shown in FIG. 3 with the cards plugged into a socket of the card edge connector system.

FIG. 5 is a cross-sectional view along lines 5-5 of FIG. 4.

FIG. 6 is a cross-sectional view along line 6-6 of FIG. 4.

FIG. 7 is a perspective view of an alternative embodiment of the present invention utilizing cards coupled to each other through a card edge connector system in a surface mount configuration.

### DETAILED DESCRIPTION OF EMBODIMENTS OF THE INVENTION

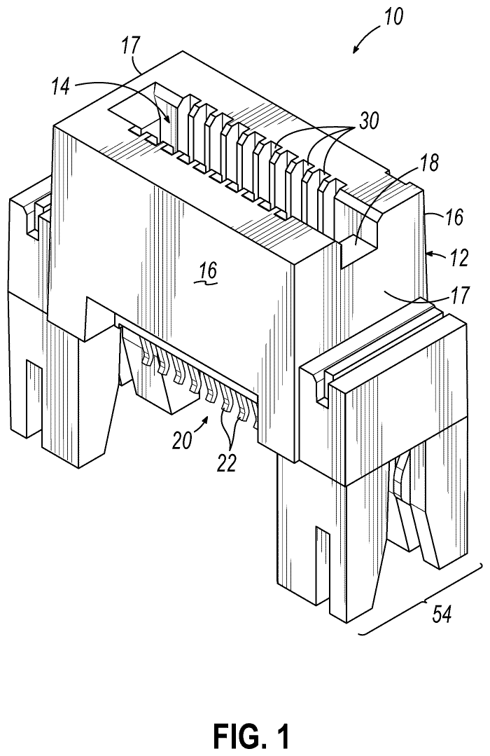

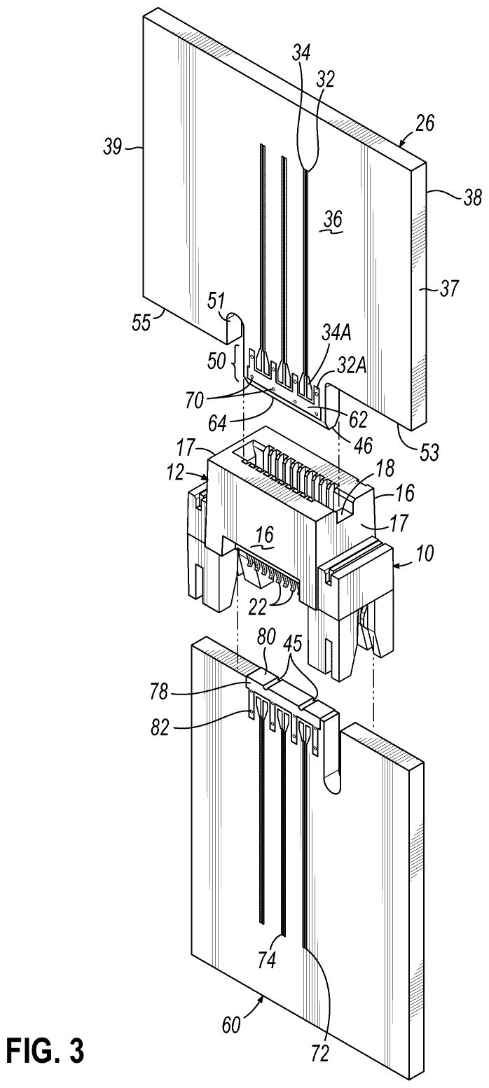

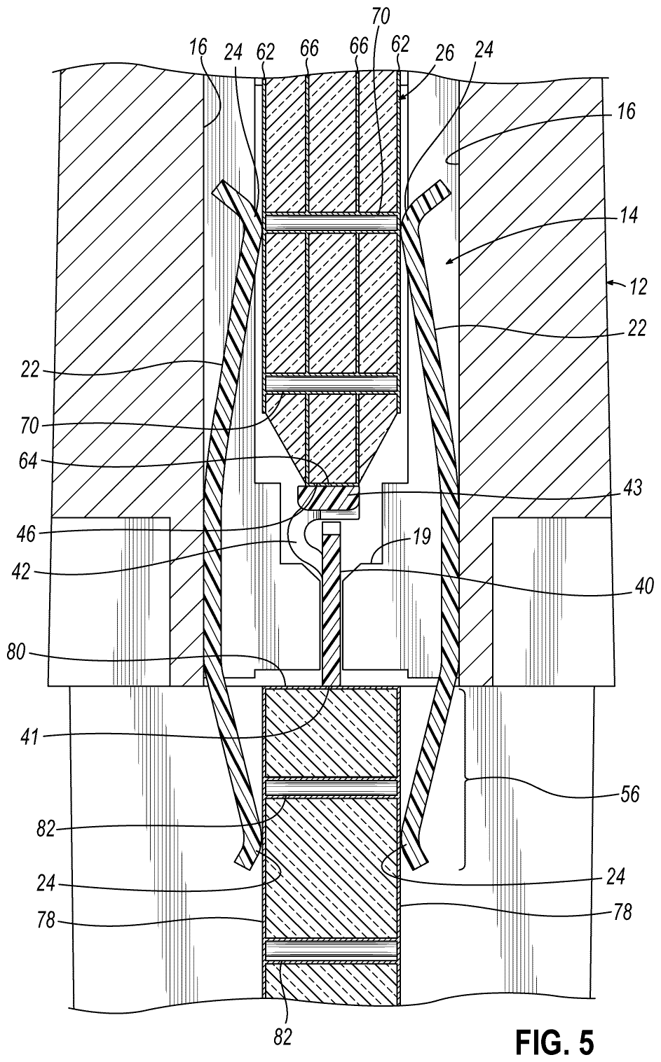

FIG. 1 illustrates an embodiment of a card edge connector system 10 in accordance with the present invention. The card edge connector system 10 includes a socket body 12 that is formed to have a socket 14 therein for receiving a printed circuit card 26 (see FIG. 3). The socket body 12 may be formed of an appropriate insulative material, such as a suitable plastic as is known in the art. The socket body 12 forms a socket configured to receive a circuit card edge and sides for making a suitable electrical connection as described herein. The socket body 12 has opposing sides 16 and a bottom 19 as illustrated in FIG. 5. The socket also includes end walls 17 that incorporate a notch 18 for alignment with the card 26 as discussed herein. The socket is configured to receive a portion of a printed circuit card providing electrical connection to the card and to electrical components on the card through the socket and the socket body 12 and card 26 incorporate features for proper alignment in use. The socket is configured to interface with a signal processing device or other device including another card or signal component as is known in the art to provide a suitable interface between the printed circuit card and another signal processing device.

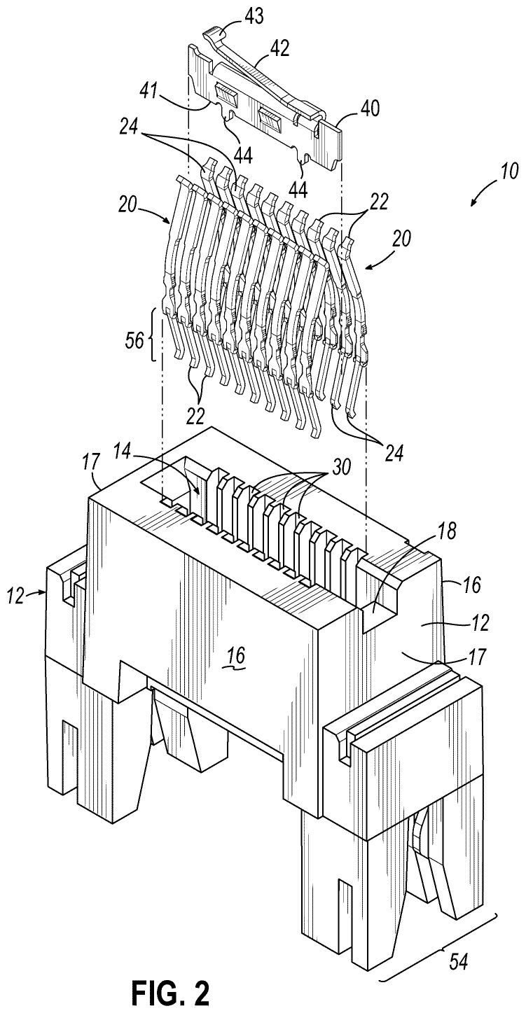

The socket contains a plurality of conductors in the form of a plurality of elongated spring elements 20 as illustrated in FIG. 2. Specifically, multiple pluralities of spring elements are located in the socket body for electrical connection. Each of the spring elements of the plurality is positioned on one of the opposing sides of the socket 14. The spring elements form a plurality of flexible spring fingers 22 on each end of the respective spring elements. The plurality of spring fingers are configured for flexing inwardly in the socket toward a centerline of the socket from the opposing sides of the socket 14 to grip the edge of the board 26. The spring elements 20 are formed of a suitable flexible and conductive metal, as is known in the art for providing signal connections between conductive signal patterns and conductive ground patterns plated on the card, in accordance with card edge connector technology. Generally, the spring elements will flex inwardly toward a side 16 of the socket to make contact with a board and the conductive patterns thereon. In the disclosed embodiment, multiple sets of spring elements are used to form opposing sets of spring elements 20 to contact both sides of the board. One set operates with another set on the opposing side of the socket. Generally, the distance between each of the ends of the spring fingers 22 and particularly the contact areas 24 of the spring fingers 22 are separated by a distance that is smaller than the thickness of a printed circuit card 26 to be received by the socket. In that way, suitable spring forces are provided against respective conductive patterns on the card 26 that line up with the spring fingers, as described herein, to effectively grip the board.

In an alternative embodiment of the invention, a single set of spring elements might be used and flex from one side of the socket. That is, a plurality of spring elements located in the socket body might be positioned along just one of the opposing sides of the socket. The spring elements would still form a plurality of spring fingers that flex inwardly in the socket to contact the card 26.

Generally, the spring elements are elongated flexible metal elements and in accordance with one embodiment the invention, the socket body includes a plurality of slots 30 formed therein for receiving and positioning and seating each of the spring elements 20 of the plurality on each of the opposing sides of the socket 14 as shown in FIG. 2. In that way, the spring elements on each side of the socket form a plurality of spring fingers 22 that deflect inwardly to the center of the socket from those opposing sides. Generally, the printed circuit card 26 will include one or more data signal patterns on one or both of the opposing sides of the card. In that way, the spring fingers engage respective signal patterns on the various sides of the card as described herein.

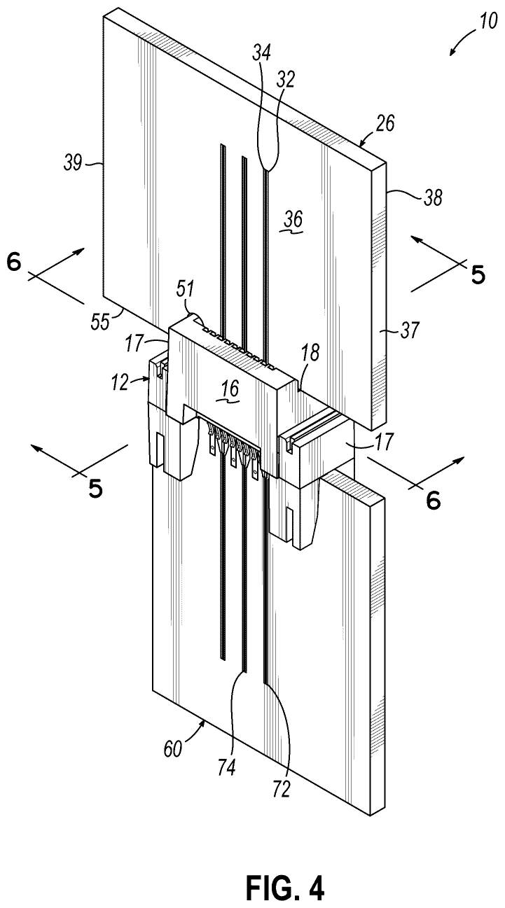

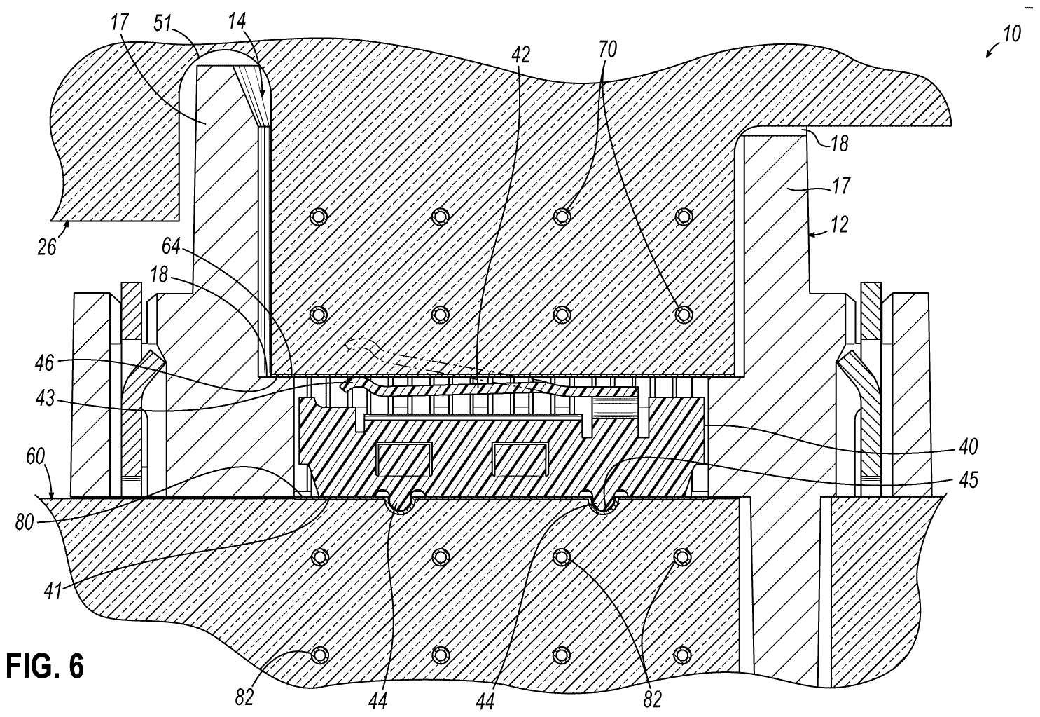

In accordance with one aspect of the invention, as illustrated in FIGS. 3, 4 and 6, the inventive system incorporates a configured printed circuit board or card 26 and socket body 12 that are configured to interface with each other in the proper orientation. The socket body 12 incorporates an alignment notch 18 and the card 26 has a counterpart notch 51 that act in cooperation to ensure alignment. Referring to FIGS. 3 and 4, for insertion of the card 26, and particularly portion 46, into the socket body 12 in the right direction for the proper signal connections between the spring fingers 22 and the contact areas on the board, alignment is necessary. For example, for alignment of the such as contact areas 32a and 34a with the proper fingers, one bottom edge 53 of the card 26 is configured to be received into the notch 18 for a proper depth of insertion of portion 50 of the card to make the properly aligned contact. As such, the notch 18 formed in wall 17 is dimensioned to receive card edge 53 as shown in FIGS. 3 and 4. The socket wall 17 at the end of the socket body opposite the wall having notch 18 is not notched, but rather forms a solid wall is shown in FIG. 3. To that end, in order to ensure proper insertion depth at that end of the socket body, notch 51 is formed in the board to receive the solid wall 17 as shown in FIGS. 4 and 6. As such, the board 26 incorporates a notch 51 in one edge 55 of card 26 to engage around the solid wall 17 while the straight edge 53 engages the socket body 12 in the notch 18. In that way, the combination of notch 18 in wall 17 and the notch 51 in card edge 55 cooperate to provide for a proper orientation of card 26 and particularly the proper orientation of the face surfaces 36, 38 of the board to ensure that the proper contact features 32, 34 aligned with the proper spring fingers 22 to ensure proper signal and grounding connections.

In accordance with another feature of the invention, a spring finger ground contact 40 is positioned on the bottom of the socket as illustrated in FIG. 5 between the sets of spring fingers 22. The ground contact 40 includes a spring finger 42 configured for flexing upwardly from the bottom wall 19 of the socket. The spring finger 42 includes a contact area 43 at a position on finger 42 as illustrated. The spring finger is configured for flexing upwardly in the socket to make contact area 43 engage a bottom edge of the card 26 to provide a ground signal or return signal path as described herein. Referring to FIG. 3, at least one printed circuit card 26 has opposing face surfaces 36, 38 and a bottom edge 46. The printed circuit card defines a portion 50 between card edges 53, 55 that is to be received into the socket 14. As noted, the notch 18 in socket body 12 and notch 51 in the card 26 ensure proper alignment between the data signal and other signal patterns 32, 34. The printed circuit card includes one or more data signal patterns 32, 34 that are plated on a side of the card for handling various signals including data signal. The pattern is plated or printed onto the side of the card utilizing conventional technology. As utilized herein the term “data signal” is not limiting but rather refers to a signal of interest that is passing through the card 26 and through the card edge connector system of the invention and to another signal handling card or circuit or device. As used herein, the term data signal will refer to one or more of the signals of interest and the terms ground signal or return signal will be referred to as ground signals as would be understood by a person of ordinary skill in the art.

Referring to FIG. 1, the socket 12 of the invention may be configured to interface with another circuit or device, such as a printed circuit card as illustrated in FIG. 3. To that end, socket 12 might be configured with a slotted portion 54 for also receiving the edge of another circuit card 60 as illustrated in FIG. 3. Generally, while spring elements 20 have portions that form spring fingers 22 that sit within the slots 30 of the socket body, the other end of the spring elements extend from the socket body at an end thereof as illustrated in FIG. 3 and form another plurality of spring fingers 22 that flex inwardly in the socket from the opposing sides 16 of the socket body. Those other plurality of spring fingers of the elements form generally a socket area 54 as shown in FIGS. 2 and 5 which are configured to engage another printed circuit card to engage one or more data signal patterns as described herein for passing signals between cards 26 and 60 in the card edge connector system 10 of the invention.

Referring again to FIG. 3, the printed circuit card 26 has one or more data signal patterns 32, 34 plated on a side of the card for handling data signals. Generally, such patterns may include contact areas 32a, 34a as illustrated for contact with the respective contact areas 24 of the spring fingers 22 when card 26 is received in the socket 14. For the ground signals or return signals, the printed circuit card also includes a ground pattern 62 that is plated on each of the opposing sides of the card (see FIG. 5) the printed circuit card also includes a ground pattern 64 that is plated on an edge 46 of the card that is received in the socket. The card 26 includes at least one ground layer, and in one embodiment a plurality of ground layers 66 that are positioned within a body of the circuit card 26.

Referring again to FIG. 5, generally the internal ground layers 66 will be formed to underlie at least a portion of the surface that is plated on each of the opposing sides of the card. Internal ground layers 66 are electrically coupled with the ground patterns 62 on opposing sides and are electrically coupled with the ground pattern 64 on the edge of the card. In that way, ground signal path or return signal path is provided both internally and externally in the printed circuit card 26. In accordance with one embodiment of the invention, one or more plated through holes 70 are formed in card 26 and extend between the ground patterns 62 plated on each of the opposing sides of the card as seen in FIG. 5. The plated through holes 70 also extend and intersect internal ground layers 66 that are positioned within the board for electrically coupling those internal layers with patterns of the opposing face surfaces 36, 38. As shown in the various figures, a plurality of through holes 70 may be implemented for providing connection between the outer patterns 62, and ground layers 66, and the edge pattern 64.

In accordance with one embodiment of the invention as illustrated in FIG. 5, the internal ground layers extend down the card to intersect the edge 46 of card 26 and engage or intersect with the ground layers or pattern 64 on the edge of the card. In that way, the internal ground layers 66 positioned within the card are electrically coupled with the ground patterns 62 through plated through holes 70 and are also coupled with the ground pattern 64 on the edge 64 of the card. As illustrated in FIGS. 4 and 5, when the portion 50 of the card 26 is received in the socket 14, the spring fingers 22 engage respective data signal patterns 32, 34 through contact areas 24 and the spring finger 42 of the spring finger ground contact 40 engage the edge of the card 26 and the pattern 64 on the edge 46. In that way, respective signal paths for data and ground signals are provided. Through engagement with the spring finger 42 and contact portion 43 thereof, the ground contact 40 of the socket 14 is provided with a suitable ground signal path to both the ground patterns 62 plated on the sides of the card and the internal ground layers 66, as well as the ground pattern on the edge of the board 64. In that way, a suitable ground signal return path is presented for card 26 at its edge 46. As illustrated in FIG. 6, the spring finger 42 will flex downwardly under tension to provide a suitable contact force against the edge pattern 64.

Referring to FIGS. 5 and 6, the spring finger ground contact 40 includes an edge 41 opposite spring finger 42. The edge 41 provides an interface to another ground pattern or ground layer in another signal handling element. In accordance with embodiments of the invention, the socket 12 may be configured to interface with another printed circuit board or card illustrated in FIGS. 5-6 and positioned edge to edge with card 26 through the card edge connector system 10. To that end, card 60 may include one or more data signal patterns 72, 74 that correspond to the data signal patterns 32, 34 in card 26 and may include a ground pattern 78 plated on each of the opposing sides of card 60 and also a ground pattern 80 plated on an edge of the card 60. As illustrated in FIGS. 3 and 5, the patterns 78 and 80 may be continuous on the edge of card 60. Furthermore, one or more plated through holes 82 might be implemented for coupling each of the side patterns 78 together in addition to the coupling provided by edge 80.

Referring to FIG. 5, the pluralities of spring fingers 22 extending from the socket body at an end thereof to form socket area of 56 are configured to receive a portion of the card 60 for electrical engagement. To that end, each of the spring fingers 22 will engage appropriate data signal patterns 72, 74 and a bottom edge 41 of the spring finger ground contact 40 engages the ground pattern 80 plated on the edge of card 60. As such, the spring finger ground contact 40, edge 41, and spring finger 42 provide a ground connection between the two cards 26 and 60 when they are plugged in to appropriate ends in an edge-to-edge relationship with the card edge connector system 10 is shown in FIG. 4. In that way, the cards 26 and 60 are generally in parallel planes and in one embodiment are generally co-planar with each other when plugged into socket 12.

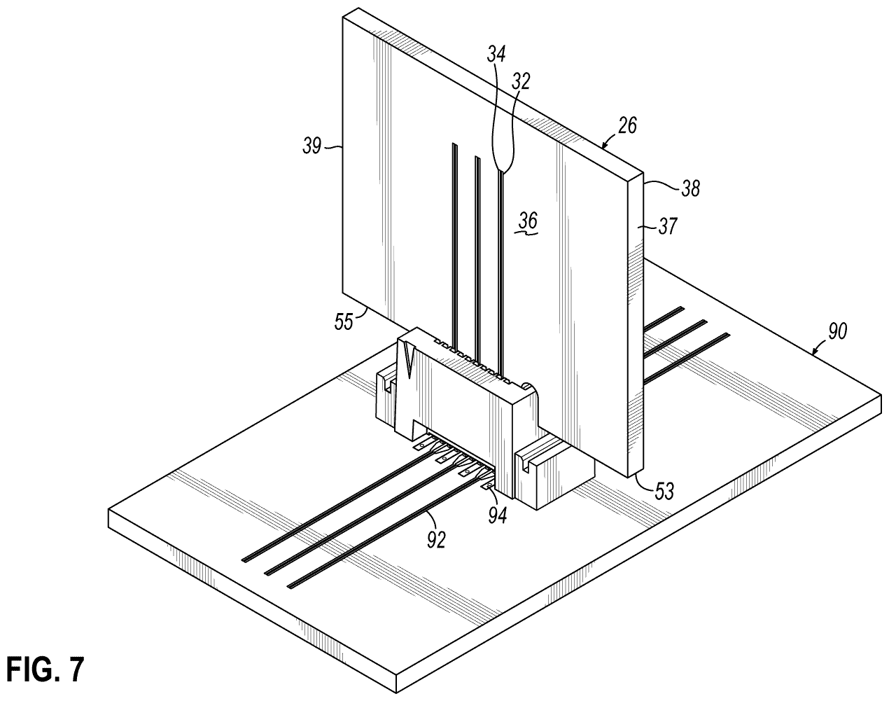

In another embodiment of the invention as illustrated in FIG. 7, the socket 12 might be used in a surface mount relationship with another card 90 for connecting cards 26 and 90 as illustrated. To that end, the card 90 may include one or more data signal patterns 92 and one or more ground patterns 94 plated on respective surfaces of the card 90. To that end, the ends of the plurality of spring elements which generally extend from the socket bodies illustrated in FIG. 1 are appropriately terminated for surface engagement with the patterns 92 on card 90. For ground connection, the edge 41 of the spring finger ground contact 40 engages with the ground patterns 94 for ground connection. To that end, the socket body 12 might be appropriately fixed to card 90 as is known in the art for providing the suitable signal connections with both data signal patterns and ground patterns on card 90. Card 26 is plugged in and appropriately engaged and connected as described herein with respect to the embodiment of FIG. 1.

In accordance with one feature of the invention, as illustrated in FIG. 6, the spring finger ground contact 40 may include one or more protrusions 44 along the lower edge 41 thereof. Then, as illustrated in FIG. 3, the card 60 may include one or more indents 45 in the edge ground pattern for receiving the protrusions 44. In that way, a more robust ground connection is provided between the bottom edge 41 of the spring finger ground contact 40 with card 60.

While the present invention has been illustrated by the description of one or more embodiments thereof, and while the embodiments have been described in considerable detail, they are not intended to restrict or in any way limit the scope of the appended claims to such detail. Various features of the motor mounting assembly 10 shown and described herein may be used alone or in any combination. Additional advantages and modifications will readily appear to those skilled in the art. The invention in its broader aspects is therefore not limited to the specific details, representative apparatus and method and illustrative examples shown and described. Accordingly, departures may be from such details without departing from the scope or spirit of the general inventive concept.

What is claimed is:

1. A card edge connector system comprising:
a socket body forming a socket having opposing sides and a bottom;
a plurality of spring elements located in the socket body and positioned along at least one of the opposing sides of the socket, the spring elements forming a plurality of spring fingers flexing inwardly in the socket;
the spring elements forming another plurality of spring fingers flexing inwardly from at least one of the opposing sides of the socket body to form a socket area proximate the bottom of the socket;
a ground contact positioned proximate the bottom of the socket and including a spring finger configured for flexing upwardly in the socket;
a printed circuit board having opposing sides and an edge and a portion to be received in the socket, the printed circuit board including at least one data signal pattern plated on a side of the board for handling a data signal;
another printed circuit board having opposing sides and an edge, the another printed circuit board including at least one data signal pattern plated on a side of the board for handling a data signal;
a ground pattern plated on each of the opposing sides of the printed circuit board and the another printed circuit board and a ground pattern plated on the respective edges of the boards;
at least one ground layer positioned within each of the printed circuit boards and electrically coupled with the ground patterns on the opposing sides and the ground pattern on the edges of the boards;
when the portion of the printed circuit board is received in the socket and the portion of the another printed circuit board is received in the socket area, at least one spring finger of each plurality of spring fingers engaging the respective data signal patterns of the respective boards and the spring finger of the ground contact engaging the edge of the printed circuit board and the ground contact engaging the edge of the another printed circuit board to provide respective signal paths for data and ground signals between the two boards.

2. The card edge connector system of claim 1 further comprising a plurality of ground layers positioned in the printed circuit board and electrically coupled with the ground patterns on the opposing sides and the ground pattern on the edge of the board.

3. The card edge connector system of claim 1 further comprising a plurality of data signal patterns plated on a side of the printed circuit board for handling data signals.

4. The card edge connector system of claim 1 further comprising a plurality of data signal patterns plated on both opposing sides of the printed circuit board for handling data signals, and including a plurality of spring elements located in the socket body and positioned along both of the opposing sides of the socket for engaging respective data signal patterns.

5. The card edge connector system of claim 1 further comprising at least one plated through hole extending between the ground patterns plated on each of the opposing sides of the board and intersecting the ground layer positioned within the board for electrically coupling the ground patterns of the opposing sides and the edge of the board.

6. The card edge connector system of claim 5 further comprising a plurality of plated through holes extending between the ground patterns plated on each of the opposing sides of the board and intersecting the ground layer positioned within the board.

7. The card edge connector system of claim 2 wherein the plurality of ground layers positioned in the printed circuit board couple with the ground pattern on the edge of the board at opposing sides of the edge.

8. The card edge connector system of claim 1 wherein the ground contact includes at least one protrusion along a lower edge thereof, the another circuit board edge including at least one indent to receive the at least one protrusion.

9. The card edge connector system of claim 1 further comprising an end wall in the socket, at least one notch formed in the end wall to receive an edge of the printed circuit board for the portion to be received in the socket.

10. The card edge connector system of claim 1 further comprising an end wall in the socket, the printed circuit board having at least one notch formed therein to receive the end wall for the portion of the printed circuit board to be received in the socket.

11. A card edge connector system comprising:
a socket body forming a socket having opposing sides and a bottom;
a plurality of spring elements located in the socket body and positioned along at least one of the opposing sides of the socket, the spring elements forming a plurality of spring fingers flexing inwardly in the socket to engage a data signal pattern plated on a side of a circuit board received in the socket;
a ground contact positioned on the bottom of the socket and including a spring finger configured for flexing upwardly in the socket for engaging a ground pattern plated on an edge of the board
the spring elements extending from the socket body at an end thereof and forming another plurality of spring fingers flexing inwardly from at least one of the opposing sides of the socket body to form a socket area to receive another printed circuit board having opposing sides and an edge to engage a data signal pattern plated on a side of the another circuit board received in the socket area;
the ground contact engaging a ground pattern plated on an edge of the another board to provide respective signal paths for data and ground signals between two boards;
the ground contact including at least one protrusion along a lower edge thereof, the another circuit board edge including at least one indent to receive the at least one protrusion.

12. The card edge connector system of claim 11 further comprising a plurality of spring elements located in the socket body and positioned along both of the opposing sides of the socket for engaging data signal patterns plated on opposite sides of a circuit board received in the socket.

13. The card edge connector system of claim 11 further comprising an end wall in the socket, at least one notch formed in the end wall to receive an edge of the printed circuit board for the portion circuit board to be received in the socket.

14. A card edge connector system comprising:
a socket body forming a socket having opposing sides and a bottom;
a plurality of spring elements located in the socket body and positioned along each of the opposing sides of the socket, the spring elements forming a plurality of spring fingers flexing inwardly in the socket to engage a data signal pattern plated on a side of a circuit board received in the socket;
a ground contact positioned on the bottom of the socket and including a spring finger configured for flexing upwardly in the socket for engaging a ground pattern plated on an edge of the board;
the spring elements extending from the socket body at an end thereof and forming surface engagement elements to engage data signal patterns on a surface of another printed circuit board having data signal patterns and ground patterns;
the ground contact including an edge positioned opposite the spring finger for engaging a ground pattern on the surface of the another board to provide respective signal paths for data and ground signals between two boards.

15. The card edge connector system of claim 14 wherein the ground contact includes at least one protrusion along the edge thereof for being received by least one indent formed in the surface of the another circuit board.
